(19) United States
(12) Patent Application Publication
(10) Pub. No.: US 2012/0161255 A1
(43) Pub. Date: Jun. 28, 2012

(54) SEALED MEMS CAVITY AND METHOD OF FORMING SAME

(75) Inventors: Thomas H. Gabert, Essex Junction, VT (US); Joseph P. Hasselbach, Burlington, VT (US); Anthony K. Stamper, Williston, VT (US)

(73) Assignee: INTERNATIONAL BUSINESS MACHINES CORPORATION, Armonk, NY (US)

(21) Appl. No.: 12/979,592

(22) Filed: Dec. 28, 2010

(51) Int. Cl. H01L 29/84; H01L 21/48

(52) U.S. Cl. 257/415; 438/51; 257/E29.324; 257/E21.002

(57) ABSTRACT

Embodiments of the invention provide methods of sealing a micro electromechanical systems (MEMS) cavity and devices resulting therefrom. A first aspect of the invention provides a method of sealing a micro electromechanical systems (MEMS) cavity in a substrate, the method comprising: forming in a substrate a cavity filled with a sacrificial material; forming a lid over the cavity; forming at least one vent hole over the lid extending to the cavity; removing the sacrificial material from the cavity; depositing a first material onto the lid such that a size of at least one vent hole at a surface of the substrate is reduced but not sealed; and depositing a second material onto the first material to seal the at least one vent hole, wherein a MEMS cavity within the substrate and beneath the at least one vent hole substantially retains a pressure at which the at least one vent hole is sealed by the second material.

### BACKGROUND

The present invention relates generally to micro electromechanical systems (MEMS) and, more particularly, to MEMS cavities and methods of sealing them.

Often, efficient use of micro electromechanical systems (MEMS) require that the cavities in which MEMS devices are contained be sealed with a particular pressure, including a sub-atmospheric or vacuum pressure. Some MEMS devices, for example, perform better and/or provide a longer operation lifetime when operating at a particular pressure. Sealing the cavity within which a MEMS device is housed at a particular pressure provides the MEMS device with a desired operating pressure and also protects the MEMS device from changes in pressure that may be experienced by unsealed portions of the device to which it is a part. It is also desirable and sometimes required to hermetically seal a MEMS cavity. Hermetic seals do not allow water to enter the cavity. The sealed cavity pressure affects MEMS performance and reliability and it can be desirable, for example, to have a room temperature cavity pressure of 1% atmosphere or less, to minimize switching time, or a room temperature cavity pressure of 10% atmosphere or greater, to reduce contact force.

One known method of sealing a MEMS cavity involves connecting together two wafers: a device wafer and a capping wafer. This approach is both expensive and results in a relatively thick seal atop the MEMS cavity. Other approaches involve a multi-step seal, in which a sealing layer is deposited atop an intermediate layer at a first temperature to reduce the size of a MEMS cavity opening, followed by “reflowing” the sealing layer at a higher temperature to seal the MEMS cavity. Such an approach adds the “reflowing” step to the sealing process, increasing both production time and expense. In addition, the higher temperature used during the “reflowing” step is often higher than the melting points of metal components of the device, resulting in risk of damage to the metal components and attendant impairment of device performance.

### SUMMARY

Embodiments of the invention provide methods of sealing a micro electromechanical systems (MEMS) cavity and devices resulting therefrom.

A first aspect of the invention provides a method of sealing a micro electromechanical systems (MEMS) cavity in a substrate, the method comprising: forming in a substrate a cavity filled with a sacrificial material; forming a lid over the cavity; forming at least one vent hole over the lid extending to the cavity; removing the sacrificial material from the cavity; depositing a first material onto the lid such that a size of at least one vent hole at a surface of the substrate is reduced but not sealed; and depositing a second material onto the first material to seal the at least one vent hole, wherein a MEMS cavity within the substrate and beneath the at least one vent hole substantially retains a pressure at which the at least one vent hole is sealed by the second material.

A second aspect of the invention provides a method of sealing a micro electromechanical systems (MEMS) cavity in a substrate, the method comprising: forming in a substrate a cavity filled with a sacrificial material; forming a lid over the cavity; forming at least one vent hole over the lid extending to the cavity; removing the sacrificial material from the cavity; depositing a first material onto the lid to a first thickness using plasma enhanced chemical vapor deposition (PECVD) at a first pressure, such that a size of at least one vent hole is reduced but not sealed by the material and deposition inside the cavity is minimized; depositing a second material to a second thickness using chemical vapor deposition over the first material to seal the at least one vent hole, wherein a MEMS cavity substantially retains the second pressure at which the at least one vent hole is sealed and the room temperature pressure inside the cavity is greater than 10% of atmospheric pressure.

A third aspect of the invention provides a semiconductor device comprising: a substrate; at least one micro electromechanical systems (MEMS) cavity; at least one MEMS device within the at least one MEMS cavity; at least one vent hole extending from a surface of the substrate to the at least one MEMS cavity; a discontinuous first material on the surface of the substrate, the first material being discontinuous over the at least one MEMS cavity and forming at least one overhang along a surface of the at least one vent hole but not extending into the at least one MEMS cavity; a second material atop the discontinuous first material, the second material being continuous over at least the one MEMS cavity.

The illustrative aspects of the present invention are designed to solve the problems herein described and other problems not discussed, which are discoverable by a skilled artisan.

### BRIEF DESCRIPTION OF THE SEVERAL VIEWS OF THE DRAWINGS

These and other features of this invention will be more readily understood from the following detailed description of the various aspects of the invention taken in conjunction with the accompanying drawings that depict various embodiments of the invention, in which:

FIG. 1 shows a cross-sectional side view of a micro electromechanical systems (MEMS) cavity in a substrate.

FIGS. 2-4 show various steps in an illustrative method of forming the MEMS cavity of FIG. 1 according to an embodiment of the invention.

FIG. 5 shows a flow diagram of a method according to an embodiment of the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

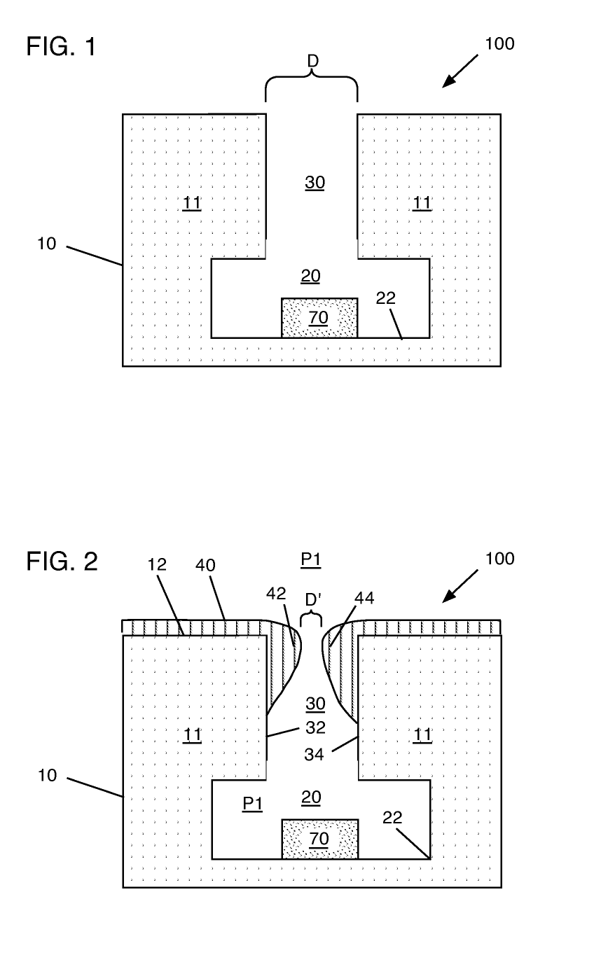

Turning now to the drawings, FIG. 1 shows a substrate 10 having a micro electromechanical systems (MEMS) cavity 20 formed therein. Substrate 10 may include any number of materials, as will be recognized by one skilled in the art. Suitable materials include, but are not limited to, crystalline and polycrystalline silicon, silicon on insulator, crystalline and polycrystalline germanium, polycrystalline silicon germanium (SiGe), glass, quartz, alumina, sapphire, polymers, metals, oxide or nitride films, silicon carbide, and materials consisting essentially of one or more III-V compound semiconductors having a composition defined by the formula Al_{X1}Ga_{X2}In_{X3}As_{Y1}P_{Y2}N_{Y3} Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable materials for substrate 10 include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Cavity 20 may be formed by any known or later-developed technique, such as ventilation or evacuation of a sacrificial material, and may be used as a MEMS cavity.

A MEMS device 70 is located within MEMS cavity 20. As shown in FIG. 1, MEMS device 70 is located on a bottom surface 22 of MEMS cavity 20, although this is not essential. MEMS device 70 may be, for example, a bulk acoustic wave filter or resonator, an accelerometer, a gyroscope, a micro tube, a sensor, a mirror, a resonator, a mechanical filter, a switch, a circuit, a cantilever beam, a bridge beam, a capacitor switch, a contact switch, or a relay. Other MEMS devices will be apparent to one skilled in the art and are intended to be within the scope of the invention. MEMS cavity 20 may be formed using any known method, such as using a sacrificial material, such as silicon, which may be vented, evacuated, or otherwise removed using XeF₂ gas, or a sacrificial material such as a spin-on polymer which may be removed using an oxygen plasma, as known in the art. A lid 11, constituting a portion of substrate 10 above MEMS cavity 20, may be formed over MEMS cavity 20 while filled with such a sacrificial material.

A vent hole 30 or other cavity opening provides access to MEMS cavity 20 through substrate 10. A sacrificial material may then be removed (e.g., vented or evacuated) from MEMS cavity 20 through vent hole 30. Vent hole 30 is shown having a size D, which may be a diameter, width, or length, depending on the shape of vent hole 30. One or more vent holes 30 may be used. As in all methods for sealing MEMS cavity 20, one challenge is to avoid or minimize depositing material into MEMS cavity 20 itself, so as to avoid impairing the function of MEMS device 70. MEMS devices can be impaired if MEMS cavity sealing material is deposited onto the top of the MEMS device, which can change the physical properties of the MEMS such as a pull-in voltage or beam shape, or if a sealing material is deposited in the contact region of the MEMS, which can increase the resistance of a contact switch or decrease a capacitance of a capacitor switch, or bond the MEMS device to lid 11 or MEMS cavity 20 walls, which restricts actuation motion of the MEMS.

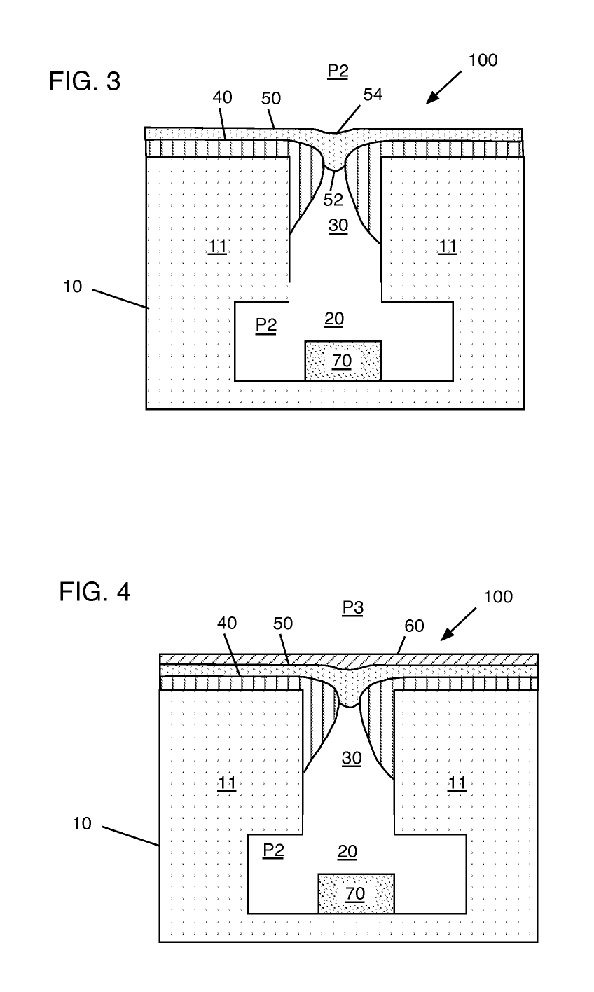

FIG. 2 shows a step according to an embodiment of the invention, wherein a first material 40, such as a silicon dioxide, is deposited by plasma enhanced chemical vapor deposition (PECVD) or physical vapor deposition (PVD) at a first pressure P1 atop a surface 12 of substrate 10. Because MEMS cavity 20 is unsealed at the stage shown in FIG. 2, first pressure P1 is imparted upon MEMS cavity 20 during the deposition only and the MEMS cavity will revert back to atmospheric pressure when the wafer is removed from the deposition tool. In some embodiments of the invention, first pressure P1 is less than about 0.01 atmospheres and the PECVD, for example, is carried out at a temperature between about 150° C. and about 450° C. In some embodiments of the invention, the PECVD is carried out at a temperature of about 400° C. Such temperatures serve to drive off any residual moisture or contaminants within MEMS cavity 20 prior to sealing. Examples of contaminants include, for example, fluorine, water, and carbon. In some embodiments of the invention, first material 40 includes a PECVD silane oxide deposited using silane, nitrous oxide, and/or oxygen precursors, or a PECVD TEOS oxide deposited using TEOS and oxygen precursors. In some embodiments of the invention, a PVD oxide is deposited using a silicon target and an oxygen plasma. Table 1 below shows the deposition inside MEMS cavity 20 under vent hole 30 for PECVD TEOS, PECVD silane, and sub-atmospheric CVD (SACVD) oxides which partially pinch off vent hole 30. All of these oxides act to partially pinch off vent hole 30 but the PECVD oxides, especially the PECVD silane oxide, have minimal deposition inside MEMS cavity 20. Although data for atmospheric pressure CVD (APCVD) oxide is not shown, it is expected that it would have similar properties to SACVD oxide since it is performed at high pressure.

TABLE 1

| | 1 μm deposition over 1.2 μm |
|---|---|
| | diameter 3 μm tall vent hole |
| | measured on a device inside |
| sealing film | the cavity directly under the vent hole |
| SACVD oxide | 300 nm |
| PECVD TEOS oxide | 100 nm |
| PECVD silane oxide | <10 nm |

First material 40 may include any material suitable for deposition, e.g., by PECVD, including, for example, silicon dioxide (SiO₂); fluorinated SiO₂ (FSG); silicon nitride, silicon carbo-nitride, hydrogenated silicon oxycarbide (SiCOH); porous SiCOH; boro-phosho-silicate glass (BPSG); silsesquioxanes; carbon doped oxides (i.e., organosilicates) that include atoms of silicon, carbon, oxygen, and/or hydrogen; thermosetting polyarylene ethers; other low dielectric constant (<3.9) materials; or combinations thereof. Other suitable materials include, for example, a metal such as titanium, tantalum, tungsten, aluminum, copper, chromium, or alloys thereof.

As can be seen in FIG. 2, first material 40 is deposited at least partially onto side walls 32, 34 of vent hole 30, forming overhangs 42, 44. It should be noted that while overhangs 42, 44 are shown in FIG. 2 and described as distinct features, the number of overhangs formed will depend, in part, on the shape of vent hole 30. For example, a vent hole having a circular or oblong cross-sectional shape may result in formation of a single overhang along the cross-sectional shape.

As a consequence of overhangs 42, 44, vent hole 30 has a reduced size D′, as compared to size D in FIG. 1. As will be recognized by one skilled in the art, overhangs 42, 44 and the reduced size D′ of vent hole 30 permit MEMS cavity 20 to subsequently be sealed by a thinner sealing layer. This is shown in FIG. 3, wherein a second material 50 is deposited by sub-atmosphere chemical vapor deposition (SACVD) or atmospheric pressure (APCVD) at a second pressure P2. Second pressure P2 may be greater than first pressure P1 and, upon sealing, is substantially retained within MEMS cavity 20. In some embodiments of the invention, second pressure P2 is greater than about 0.1 atmospheres, e.g., greater than about 0.2 atmospheres. In some embodiments, second pressure P2 is about 0.5 atmospheres. In other embodiments of the invention, second pressure P2 may be an atmospheric pressure or a pressure greater than atmospheric pressure. Note that, if second material 50 is deposited at elevated temperatures, e.g. 400° C., then the second pressure P2, at room temperature, will be more than 50% lower, as determined by the Ideal Gas Law, where cavity pressure is proportional to temperature. Table 2 below shows the deposition inside the cavity for PECVD TEOS, PECVD silane, and SACVD oxides to seal a partially pinched off vent hole.

TABLE 2

| | 0.5 μm deposition over partially |
|---|---|
| | pinched off 1.2 μm diameter |
| | vent hole with a 0.3 μm opening |
| | on a device inside the cavity |
| sealing film | directly under the vent hole |
| SACVD oxide | 60 nm |
| PECVD TEOS oxide | 20 nm |
| PECVD silane oxide | <10 nm |

In some embodiments of the invention, SACVD deposition of second material 50 may be carried out at a temperature between about 150° C. and about 450° C. In some embodiments, the SACVD deposition temperature may be about 400° C.

As shown in FIG. 3, a projecting portion 52 of second material 50 may project into vent hole 30 during sealing, resulting in a depression 54 above vent hole 30. Whether and the extent to which projecting portion 52 and depression 54 may form will depend, for example, on the SACVD conditions and the material(s) of second oxide layer 50.

As noted above, overhangs 42, 44 (FIG. 2) and the reduced size D′ (FIG. 2) of vent hole 30 facilitate sealing of MEMS cavity 20 using relatively less material than first material 40. Therefore, second material 50 may have a thickness less than that of first material 40. In some embodiments of the invention, first material 40 has a thickness of about 0.6 micrometers while second material 50 has a thickness of about 0.4 micrometers, i.e., a ratio of about 3:2. In other embodiments of the invention, the thickness ratio of first material 40 to second material 50 may be less than about 3:2, e.g., about 2:1 or less than about 2:1. It is important that the second material 50 completely seals off all vent holes 30 so that the cavity pressure is determined by the pressure and temperature during the deposition of the second material 50.

One advantage of the above-described embodiments of the invention is the reduced processing time resulting from PECVD deposition of the thicker first material 40, which is much faster than SACVD or APCVD deposition. Another advantage of some embodiments of the invention is the reduction or elimination of deposition of second material 50 inside MEMS cavity 20, as shown above in Tables 1 and 2. As noted above, less material is needed for second material 50 than in other sealing methods. When highly conformal materials are used in second material 50, the reduction in necessary material reduces the likelihood of deposition inside MEMS cavity 20. Even in embodiments of the invention in which non-highly conformal materials are used, overhangs 42, 44 and reduced size D′ decrease both the amount of material needed in second material 50 and the likelihood that such material will be deposited inside MEMS cavity 20.

In some embodiments it is desirable to seal the cavity at lower pressures, i.e. at the pressure used by a PECVD process, but it is undesirable to seal MEMS cavity 20 with a silane oxide, due to concerns about MEMS stiction or other problems related to sealing MEMS cavity 20 in a silane and nitrous oxide or oxygen ambient. In such cases, a silane oxide may be used for first material 40 and a PECVD TEOS oxide may be used for the second material 50. This minimizes oxide deposition inside the cavity but seals MEMS cavity 20 with a TEOS and oxygen process, which can improve MEMS properties such as stiction.

In other embodiments of the invention, first material 40 may be deposited using physical vapor deposition (PVD) and/or second material 50 may be deposited using atmospheric pressure chemical vapor deposition (APCVD). The deposition techniques used will depend, for example, on the pressure at which MEMS cavity 20 is to be sealed.

In some embodiments of the invention, a hermetic seal may be applied atop second material 50 to protect it from ambient moisture. In FIG. 4, a hermetic layer 60 has been deposited atop second material 50 using PECVD. Hermetic layer 60 may include silicon nitride, as known in the art and may be deposited using any method, such as PECVD. Hermetic layer 60 typically needs to be thick to provide hermetic protection. In some embodiments, hermetic layer 60 is less than half the thickness of second material 50, e.g., about 0.1 micrometers in the case that second material 50 is about 0.4 micrometers thick. Alternatively, hermetic layer 60 may be several microns thick to prevent damaging or cracking the MEMS cavity during packaging.

As can be seen in FIG. 4, the pressure P3 at which hermetic layer 60 is deposited does not affect the pressure of MEMS cavity 20, which substantially retains second pressure, P2, regardless of whether P3 is higher or lower than P2. Materials suitable for use in hermetic layer 60 include, but are not limited to, silicon nitride and carbo-nitrides, and other materials known in the art.

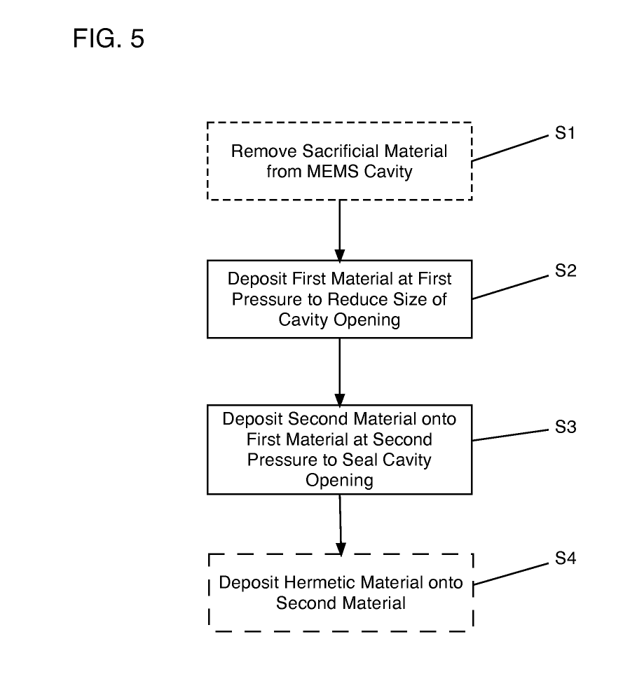

FIG. 5 shows a flow diagram of a method according to an embodiment of the invention. At S1, a sacrificial material within a MEMS cavity 20 may optionally be removed, if it has not already been so removed. As noted above, such removal may be by, for example, photolithographic printing of vent holes through lid 11 and removing (e.g., by venting or evacuating) the sacrificial material.

At S2, a first material is deposited at a first pressure P1 onto a substrate. Such deposition reduces a size D of a vent hole 30 above MEMS cavity 20 but does not seal vent hole 30. As noted above, the first material may be deposited by, for example, PECVD or PVD.

At S3, a second material 50 is deposited at a second pressure P2 onto first material 40, which seals MEMS cavity 20. The pressure within sealed MEMS cavity 20 is, therefore, substantially the same as second pressure P2. As noted above, second material 50 may be deposited by, for example, SACVD or APCVD.

At S4, a hermetic layer 60 may be deposited onto second material 50 to hermetically seal second material 50 from ambient moisture. As noted above, hermetic layer 60 may be formed by, for example, PECVD.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of sealing a micro electromechanical systems (MEMS) cavity in a substrate, the method comprising:
forming in a substrate a cavity filled with a sacrificial material;
forming a lid over the cavity;
forming at least one vent hole over the lid extending to the cavity;
removing the sacrificial material from the cavity;
depositing a first material onto the lid such that a size of at least one vent hole at a surface of the substrate is reduced but not sealed; and
depositing a second material onto the first material to seal the at least one vent hole,
wherein a MEMS cavity within the substrate and beneath the at least one vent hole substantially retains a pressure at which the at least one vent hole is sealed by the second material.

2. The method of claim 1, wherein a post sealing cavity pressure at room temperature is greater than about 0.05 atmospheres.

3. The method of claim 2, wherein the post sealing cavity pressure during the deposition of the second material is greater than about 0.1 atmospheres.

4. The method of claim 3, wherein the first material is deposited using PVD at a pressure of about less than 0.01 atmospheres.

5. The method of claim 1, wherein the depositing the first material includes depositing the first material at a temperature between about 150° C. and about 450° C. using plasma enhanced chemical vapor deposition (PECVD) and the depositing the second material includes depositing the second material at a temperature between about 150° C. and about 450° C. using at least one of the following: sub-atmospheric pressure chemical vapor deposition (SACVD) or atmospheric pressure chemical vapor deposition (APCVD).

6. The method of claim 5, wherein the depositing a first material includes minimizing deposition inside the cavity.

7. The method of claim 5, wherein at least one of the depositing the first material and the depositing the second material includes depositing at least one of the first material and the second material at a temperature of about 400° C.

8. The method of claim 1, wherein the depositing the first material includes depositing the first material to a first thickness and the depositing the second material includes depositing the second material to a second thickness such that each of the at least one vent hole is sealed.

9. The method of claim 1, wherein each of the first material and the second material is independently selected from a group consisting of: silane oxide; silicon dioxide (SiO₂); fluorinated SiO₂ (FSG); hydrogenated silicon oxycarbide (SiCOH); porous SiCOH; boro-phosho-silicate glass (BPSG); silsesquioxanes; carbon doped oxides that include atoms of silicon, carbon, oxygen, and/or hydrogen; thermosetting polyarylene ethers; other low dielectric constant (<3.9) materials; a metal, including titanium, tantalum, tungsten, aluminum, copper, chromium, or alloys thereof; and combinations thereof.

10. The method of claim 1, further comprising:
depositing a hermetic material onto the second material using plasma enhanced chemical vapor deposition.

11. The method of claim 1, further comprising:
forming the at least one vent hole, each with about a 1.2 micron diameter and a round or octagonal shape, wherein depositing the first material includes depositing the first material to about 1.3 microns and depositing the second material includes depositing the second material to about 0.8 microns.

12. The method of claim 10, wherein the hermetic material seals the MEMS cavity from ambient moisture and is selected from a group consisting of: a silicon nitride and a carbo-nitride.

13. A method of sealing a micro electromechanical systems (MEMS) cavity in a substrate, the method comprising:
forming in a substrate a cavity filled with a sacrificial material;
forming a lid over the cavity;
forming at least one vent hole over the lid extending to the cavity;
removing the sacrificial material from the cavity;
depositing a first material onto the lid to a first thickness using plasma enhanced chemical vapor deposition (PECVD) at a first pressure, such that a size of at least one vent hole is reduced but not sealed by the material;
depositing a second material onto the first material to a second thickness using chemical vapor deposition at a second pressure to seal the at least one vent hole,
wherein a MEMS cavity substantially retains the second pressure at which the at least one vent hole is sealed by the second material.

14. The method of claim 13, wherein the second pressure is greater than about 0.1 atmospheres during deposition and the depositing the second material occurs at a temperature between about 150° C. and about 450° C.

15. The method of claim 13, wherein the material is selected from a group consisting of: silane oxide; silicon dioxide (SiO₂); fluorinated SiO₂ (FSG); hydrogenated silicon oxycarbide (SiCOH); porous SiCOH; boro-phosho-silicate glass (BPSG); silsesquioxanes; carbon doped oxides that include atoms of silicon, carbon, oxygen, and/or hydrogen; thermosetting polyarylene ethers; other low dielectric constant (<3.9) materials; a metal, including titanium, tantalum, tungsten, aluminum, copper, chromium, or alloys thereof; and combinations thereof.

16. The method of claim 15, wherein the first material includes PECVD silicon dioxide deposited using silane as a silicon source and any known oxidizer.

17. The method of claim 13, further comprising:
depositing a hermetic layer onto the second material.

18. The method of claim 13, wherein the second pressure substantially retained by the MEMS cavity is greater than about 10% of atmospheric pressure at room temperature.

19. A semiconductor device comprising:
a substrate;
at least one micro electromechanical systems (MEMS) cavity;
at least one MEMS device within the at least one MEMS cavity;
at least one vent hole extending from a surface of the substrate to the at least one MEMS cavity;
a discontinuous first material on the surface of the substrate, the first material being discontinuous over the at least one MEMS cavity and forming at least one overhang along a surface of the at least one vent hole but not extending into the at least one MEMS cavity;
a second material atop the discontinuous first material, the second material being continuous over at least the one MEMS cavity.

20. The microelectronic device of claim 19, further comprising:
a hermetic layer atop the second material.

21. The microelectronic device of claim 19, further comprising:
a sealed cavity with a room temperature pressure between about 0.05 and 0.95 atmospheres.

22. The microelectronic device of claim 19, wherein each of the first material and the second material includes at least one material independently selected from a group consisting of: silane oxide; silicon dioxide (SiO₂); fluorinated SiO₂ (FSG); hydrogenated silicon oxycarbide (SiCOH); porous SiCOH; boro-phosho-silicate glass (BPSG); silsesquioxanes; carbon doped oxides that include atoms of silicon, carbon, oxygen, and/or hydrogen; thermosetting polyarylene ethers; other low dielectric constant (<3.9) materials; a metal, including titanium, tantalum, tungsten, aluminum, copper, chromium, or alloys thereof; and combinations thereof.
